(19) United States
(12) Patent Application Publication
(10) Pub. No.: US 2024/0306311 A1
(43) Pub. Date: Sep. 12, 2024

(54) Connection of Two Components with One Connecting Element

(71) Applicant: NanoWired GmbH, Gernsheim (DE)

(72) Inventors: Olav Birlem, Gernsheim (DE); Florian Dassinger, Gernsheim (DE); Sebastian Quednau, Gernsheim (DE); Farough Roustaie, Gernsheim (DE)

(21) Appl. No.: 18/283,576

(22) PCT Filed: Mar. 15, 2022
(86) PCT No.: PCT/EP2022/056695

§ 371 Date: Sep. 22, 2023

(30) Foreign Application Priority Data
Mar. 29, 2021 (DE) 10 2021 107 824.5

(51) Int. Cl. H05K 3/32

(52) U.S. Cl. CPC H05K 3/32; H05K 2201/10962

(57) ABSTRACT

Connection elements each with a plurality of nanowires on a first connection face and/or on a second connection face opposite the first connection face, wherein a distance (d) between the first connection face and the second connection face varies over the connection element.

The invention relates to the connection of two components, in particular electronic or thermal components, using a connection element via a plurality of nanowires. In particular, the invention relates to a corresponding connection element, a method for producing such a connection element, a method for connecting two components, and an arrangement formed of two interconnected components.

It is known to connect electronic, mechanical or thermal components to one another via a plurality of nanowires. If the faces to be connected of the components are uneven, however, such a connection cannot be formed using the known solutions or can only be formed poorly. This is due to the fact that nanowires can only be grown with a limited length. Correspondingly, the nanowires can compensate only to a limited extent for unevennesses in the faces to be connected. If the unevennesses of the faces to be connected are too great, the connection cannot be formed over the full area. This has an adverse effect on the mechanical stability, the electrical conductivity and/or the thermal conductivity of the connection.

The object of the present invention, proceeding from the described prior art, is to present a way of connecting two components to one another, in a particularly stable, electrically conductive and/or thermally conductive manner, in spite of uneven contact faces. To this end, a connection element that can be used in a particularly versatile manner is to be presented.

These objects are achieved by a connection element, a method for producing a connection element, a method for connecting a first component to a second component, and an arrangement according to the independent claims. Further advantageous embodiments are described in the dependent claims. The features presented in the claims and in the description are combinable with one another in any technically feasible way.

In accordance with the invention, a connection element having a plurality of nanowires is placed on a first connection face and/or on a second connection face opposite the first connection face. A distance between the first connection face and the second connection face varies over the connection element.

The connection element is preferably designed to connect a first component to a second component. The connection element has a varying thickness and can thus compensate well for unevennesses on the contact faces to be connected of the components.

The components can each be, in particular, an electronic component such as a semiconductor component, a computer chip, a microprocessor, a circuit board or a heat sink. The advantages of the described connection element manifest themselves particularly when the components each have a contact face for connection to the other component, wherein the contact faces arranged relative to one another are not plane-parallel to one another. It is particularly advantageous if a heat-transferring element, for example in the form of a heat sink, is to be connected as a first component to a heat-emitting substrate, for example a semiconductor component, as a second component.

Whereas heat-conducting elements usually have a flat contact face, the contact face in heat-emitting substrates is often curbed inwardly or outwardly. This can be compensated for by means of the described connection element, in particular by one of the two connection faces being curved negatively relative to the contact face of the heat-emitting substrate.

The components are preferably at least partially electrically and/or thermally conductive. An electric and/or thermal conductivity in the sense used here is provided in particular with metals, such as copper, which are said generally to be “electrically conductive” or, synonymously, “electrically conducting” and “thermally conductive” or “thermally conducting”. In particular, materials considered generally to be electrically and thermally insulating are not considered here to be electrically and thermally conductive.

The connection element, however, is not limited to uses in the field of electronics. In particular, a mechanically stable, electrically and/or thermally conductive connection between two components can be formed using the connection element. The connection element can thus be used in all fields in which a connection between two components having one or more of these properties is necessary. The use of the connection element is also not limited to a specific size of the components. The connection element can thus be designed, for example, for use in the field of (micro)electronics of a few mm² or for connection of much larger contact faces at macroscopic level, such as heat sinks of many cm².

The connection element can be connected on the one hand to the first component and on the other hand to the second component. In this regard, the components can be connected to one another indirectly via the connection element. The connection element can thus be interpreted as a facilitator of the connection between the first component and the second component. In particular, any physical object that is suitable for bridging contact faces of two components in order to connect the components can be considered to be a connection element.

The connection element is preferably formed as a film. Instead of the term ‘connection element’, the term ‘connection film’ can also be used in this case. In particular, it is preferred that the connection element is flexible. Alternatively, it is preferred that the connection element is rigid. The connection element can thus be designed, for example, as a fixed metal plate.

It is preferred that the connection element is formed from a plastics material. For example, the connection element can be formed from a polymer, in particular from polycarbonate, PVC, polyester, polyethylene, polyamide and/or PET. The connection element can also be formed, for example from a ceramic material, silicon, aluminium oxide or glass. Furthermore, the connection element can be formed from stainless steel, aluminium or non-ferrous metal. It is also preferred that the connection element is formed from a composite material comprising multiple of the stated materials.

The connection element has two connection faces arranged opposite one another. The first connection face is preferably formed on a first side of the connection element. The second connection face is preferably formed on a second side of the connection element, opposite the first side. The first connection face can cover a part of the first side of the connection element or the entire first side of the connection element. The second connection face can cover a part of the second side of the connection element or the entire second side of the connection element. The fact that the two connection faces are arranged opposite one another implies that the two connection faces overlap one another at least in part. The two connection faces preferably overlap one another fully.

One connection face is, in particular, a spatially defined region of a surface of the connection element on the relevant side of the connection element. In particular, it is preferred that the connection faces are distinguished by the forming of the connection. This means that the connection faces are initially indifferentiable from the rest of the surface of the connection element and only become apparent by the forming of the connection, in such a way that the connection faces are faces where the connection is formed. In this case, the connection faces are only theoretically distinguished from the rest of the surface of the connection element. For example, a connection face of a planar connection element can be distinguished in that a planar connection to the contact face of a component is formed by means of a delimited area of the connection element (i.e. by means of the connection face).

The connection faces are preferably as large as a contact face to be connected thereto of a component and in particular preferably have the shape of this contact face. However, it is also possible that the contact faces are larger or smaller than the corresponding connection faces and/or that the contact faces and the corresponding connection faces have different shapes.

The connection faces are preferably each single cohesive regions of the surface of the connection element. Alternatively, it is possible that the first connection face and/or the second connection face are divided into a plurality of separate sub-regions of the surface of the connection element. For example, a connection face can comprise two or more separate portions of the surface of the connection element.

A plurality of nanowires is arranged on the first connection face or on the second connection face or on the first connection face and on the second connection face. The latter “and” variant is preferred. The connection element, however, can also be used for the connection of two components if it has nanowires only on one side. The corresponding component in this case can be connected to the connection element for example by nanowires on the component. It is also conceivable that the component is connected in some other way to the connection element, for example by gluing.

A nanowire is understood here to mean any material body that has a wire-like form and measures from a few nanometres in size to a few micrometres. A nanowire can have a circular, oval or polygonal base area, for example. In particular, a nanowire can have a hexagonal base area.

All nanowires on the first connection face are preferably formed from the same material, in particular from the material of the first connection face. All nanowires in the second connection face are preferably formed from the same material, in particular from the material of the second connection face. The nanowires on the first connection face are preferably formed from the same material as the nanowires on the second connection face. Alternatively, it is preferred that the nanowires on the first connection face and the nanowires on the second connection face are formed from different materials.

It is particularly preferred that the nanowires on the first connection face are formed from the same material as the contact face of the first component and/or that the nanowires on the second connection face are formed from the same material as the contact face of the second component. This is the case when the connection element is provided together with a first component and/or a second component in the form of an arrangement.

The nanowires are preferably formed from an electrically and/or thermally conductive material, in particular from a metal. Copper is particularly preferred.

The nanowires preferably have a length in the range of 100 nm [nanometres] to 100 μm [micrometres], in particular in the range of 500 nm to 60 μm. Furthermore, the nanowires preferably have a diameter in the range of 10 nm to 10 μm, in particular in the range of 30 nm to 2 μm. Here, the term ‘diameter’ refers to a circular base area, and in the case of a base area deviating herefrom a comparable definition of a diameter will be used. It is particularly preferred that all used nanowires have the same length and the same diameter.

The nanowires are preferably perpendicular to the particular connection face. The nanowires are in this case arranged in a lawn-like manner on the particular connection face.

A distance between the first connection face and the second connection face varies over the connection element. The distance between the first connection face and the second connection face can also be interpreted as a thickness of the connection element. If the connection element is formed as a film, the distance between the first connection face and the second connection face describes the thickness of the film. The distance between the connection face and the second connection face is defined as the distance between a point on one of the connection faces to the closest point on the other connection face. Consequently, a value for the distance between the first connection face and the second connection face can be specified for each point of the connection element. The fact that the distance between the first connection face and the second connection face varies over the connection element means that the distance between the first connection face and the second connection face does not have the same value at all points of the connection element. It is not necessary that the distance between the first connection face and the second connection face has a different value at each point of the connection element. In addition, the nanowires also contribute to the compensation of unevennesses of the contact faces. It is therefore not necessary that the shape of the connection element conforms exactly to the shape of the corresponding contact faces. This is all the more true if the connection element is used to connect two components which each likewise have a plurality of nanowires on their respective contact faces. In this case the nanowires on the connection element connect to the nanowires of the particular component, which is also possible in the case of a relatively large distance between the connection face and contact face.

Generally, the nanowires can compensate for microscopic unevennesses, whereas macroscopic unevennesses can be compensated for by the shape of the connection element.

Due to the design of the connection element with varying distance between the first connection face and the second connection face, the connection element can be used particularly well to connect components to one another that have uneven contact faces. Ideally, the connection faces of the connection element are exactly complementary to the contact face of the component to be connected. Such a conformity, however, requires an exact conformity of the connection element to the components to be connected and consequently presupposes knowledge of the components. It has been found, however, that a connection element with varying distance between the first connection face and the second connection face generally improved the quality of the connection. The described advantages with the described connection element as such can thus be achieved independently of the design of the components. This can be explained in that the connection element designed as described will position itself between the two components such that a particularly good connection between the components is achieved. This would not be the case with a connection element with constant distance between the connection faces, because such a connection element is formed identically at all points.

In a preferred embodiment of the connection element, one of the connection faces is curved and the other of the connection faces is flat.

In this embodiment either the first connection face is curved and the second connection face is flat, or the second connection face is curved and the first connection face is flat. The curved connection face in both cases can be curved inwardly or outwardly. In the case of an inward curvature, the distance between the first connection face and the second connection face at the edge of the connection faces is greater than at their centre. An inward curvature can also be said to be concave. In the case of an outward curvature, the distance between the first connection face and the second connection face at the edge of the connection faces is smaller than at their centre. An outward curvature can also be said to be convex. Similarly to the naming that is conventional in the case of optical lenses, the connection element in the present embodiment in the case of an inwardly curved connection face can be said to be plano-concave and in the case of an outwardly curved connection face can be said to be plano-convex.

The described embodiment with a flat connection face can be produced particularly easily, in particular by stamping. The connection element can be placed on a flat substrate and can be brought into the desired shape by the action of pressure, wherein only the connection face distanced from the substrate is deformed.

In a further preferred embodiment of the connection element, one of the connection faces is curved outwardly and the other of the connection faces is curved inwardly with a different radius of curvature.

In this embodiment either
the first connection face is curved outwardly (convexly) with a first radius of curvature and the second connection face is curved inwardly (concavely) with a second radius of curvature
or
the first connection face is curved inwardly (concavely) with a first radius of curvature and the second connection face is curved outwardly (convexly) with a second radius of curvature.

In both cases the first radius of curvature and the second radius of curvature are different. If the first radius of curvature and the second radius of curvature were to be identical, the distance between the first connection face and the second connection face would be constant.

If the radius of curvature of the outwardly curved connection face is smaller than the radius of curvature of the inwardly curved connection face, reference can be made to a concave-convex shape of the connection element, similarly to the naming that is conventional in the case of optical lenses. If the radius of curvature of the outwardly curved connection face is greater than the radius of curvature of the inwardly curved connection face, reference can be made to a convex-concave shape of the connection element, similarly to the naming that is conventional in the case of optical lenses.

The described design with connection faces curved in opposite directions is more complex to produce than the previously described design with a flat connection face. For example, stamping with a correspondingly shaped die and a correspondingly shaped punch is possible. It has been found, however, that a better quality of the connection can be obtained in exchange. In particular, it is true for this case that components of which the contact faces are curved in opposite directions with different radii of curvature are to be connected to one another. Here, a curvature in opposite directions is understood to mean that the contact face of the first component is curved inwardly and the contact face of the second component is curved outwardly, or vice versa.

In a further preferred embodiment of the connection element, the connection faces are both curved inwardly or both curved outwardly.

If both connection faces are curved inwardly, reference can be made to a biconcave shape of the connection element, similarly to the naming that is conventional in the case of optical lenses. If both connection faces are curved outwardly, reference can be made to a biconvex shape of the connection element, similarly to the naming that is conventional in the case of optical lenses.

In both cases the radii of curvature of the two connection faces are arbitrary. It is preferred for reasons of symmetry that both connection faces are curved with the same radius of curvature.

The described embodiment with connection faces curved in the same direction is more complex to produce than the design with a flat connection face. For example, it is possible to perform the stamping with a correspondingly shaped die and a correspondingly shaped punch. It has been found, however that an even better quality of the connection can be achieved in exchange. This is true in particular for the case that components of which the contact faces are curved in the same direction are to be connected to one another. A curvature in the same direction is understood here to mean that the contact faces of both components are curved inwardly or that the contact faces of both components are curved outwardly.

In the embodiments described above, the variation of the distance between the first connection face and the second connection face is realized by a curvature of one or both connection faces. This is not necessary, however. Alternatively, the connection faces can also have any conceivable other shape resulting in a distanced between the two connection faces which is not constant over the connection element. For example, one or both connection faces can be corrugated or can have a different recurrent structure. One or both connection faces can also have a non-recurrent structure. The shape of the connection faces is particularly preferably adapted to the contact face of the component to be connected.

As a further aspect of the invention, a method for producing a connection element is presented. The method comprises:
a) providing a starting element having a first connection face and a second connection face opposite the first connection face, wherein a distance between the first connection face and the second connection face is constant over the starting element,
b) deforming the starting element so that the distance between the first connection face and the second connection face varies over the starting element,
c) growing a plurality of nanowires on the first connection face and/or on the second connection face of the starting element, whereby the connection element is obtained.

The described advantages and features of the connection element are applicable and transferrable to the method, and vice versa. The previously described connection element can be produced with the connection element.
Steps a) to c) are performed in the stated order.

The connection element is obtained from the starting element provided in step a). The starting element provided at the start of the method thus differs from the connection element merely by properties that are changed by the described method. This relates in particular to the shape of the starting element. The distance between the first connection face and the second connection face is initially constant over the starting element. In step b) this is changed by deformation. The starting element obtains the form of the connection element by step b). In step c) the nanowires are grown on the connection faces. This can be achieved by galvanic growth. For example, a template film with a plurality of pores passing through it can be placed on a connection face. The nanowires can be grown in the pores by deposition from an electrolyte. In step c) the nanowires can be grown first on the first connection face and then on the second connection face, or vice versa. It is also conceivable to grow the nanowires on both connection faces at the same time.

The nanowires are preferably provided on the connection faces in such a way that they stand substantially upright (preferably upright) on the particular connection face. The totality of the nanowires on a connection face can be referred to in particular as a lawn of nanowires. The nanowires, however, can also be provided on the connection faces in any orientation. It is also possible that a connection face is divided into a plurality of sub-regions (connection to one another or separate from one another), wherein the nanowires in the various sub-regions are oriented differently from one another. A particularly stable connection can thus be realized, which in particular can withstand also shear forces particularly well. It is furthermore possible that the nanowires are embodied differently at different points of the connection faces, in particular in respect of their length, diameter, material and density (wherein the density of the nanowires specifies how many nanowires are provided per area).

In a preferred embodiment of the method the starting element is deformed in step b) by stamping.

The connection element can achieve a precise predefined form as a result of stamping. Here, the connection element can be adapted to two components that are to be connected to one another.

As a further aspect of the invention, a method for connecting a first component to a second component is presented. The method comprises:
A) providing a connection element having a plurality of nanowires on a first connection face and/or on a second connection face opposite the first connection face, wherein a distance between the first connection face and the second connection face varies over the connection element,
B) bringing together a contact face of the first component with the first connection face of the connection element and bringing together a contact face of the second component with the second connection face of the connection element.
   The described advantages and features of the connection element and of the method for producing the connection element are applicable and transferrable to the method for connecting the first component to the second component, and vice versa. The connection element used in the method for connecting the first component to the second component is preferably formed similarly to the previously described connection element.

Steps A) and B) are performed in the stated order. In step A) the connection element is provided. In step B) the components are connected to one another via the connection element. To this end, the contact face of the first component is brought together with the first connection face, and the contact face of the second component is brought together with the second connection face of the connection element. This can be performed in any order successively or simultaneously. Here, ‘bringing together’ means that the component in question and the connection element are moved towards one another. The nanowires on the connection faces thus come into contact with the corresponding contact face. Here, the nanowires connect to the corresponding contact face, whereby the corresponding connection between the components and the connection element is formed.

The connection can be formed in that the nanowires, in particular their ends facing the corresponding contact face, connect to the contact face. To this end it is not necessary that nanowires are likewise provided on the contact face. The connection can thus be formed directly between the nanowires on the connection element and the contact face itself. In particular in this case it is preferred that at least the contact face is heated to a temperature of at least 90° C., in particular of at least 150° C. This connection can be formed at atomic level. The process occurring atomically here is similar to that which occurs during sintering. The obtained connection in particular can be impervious to gases and/or liquids, in such a way that corrosion of the connection and/or of the interconnected components in the region of the connection can be prevented or at least limited. In particular, the formed connection can be considered to be fully metallic. Alternatively, the nanowires serve for brush-like contacting of the contact face, in which the nanowires nestle against the contact face in part and thus form the connection. As a further alternative, it is possible that a plurality of nanowires is also provided on the contact face to be connected. In this case, the connection between the nanowires on the connection face and the nanowires on the corresponding contact face can be formed. Here, the nanowires on the connection face are interwoven with the nanowires on the corresponding contact face, such that a particularly close connection between the connection element and the corresponding component is created. In particular if a plurality of nanowires is also provided on the contact face, the connection can also be formed without heating, in particular at room temperature.

Unevennesses and roughnesses in the contact faces can be compensated for by the plurality of nanowires insofar as this is not already done by the shape of the connection element.

Due to the size of the nanowires in the nanometre range, the surface of the connection (i.e. the area over which forces such as Van-der-Waals force act at atomic level) is particularly large. The connection can be particularly effectively electrically and/or thermally conductive and/or mechanically stable for this purpose. For an electrically and/or thermally particularly conductive connection it is preferred that the nanowires are formed from an electrically and/or thermally conductive material. The use of copper is particularly preferred here. The contact faces are also preferably formed from an electrically and/or thermally conductive material, in particular with copper. The use of copper would not be possible, for example in the case of a welded connection. Due to the large surface of the connection obtained by the described method, an electrical and/or thermal conductivity of the connection can be particularly high. A particularly good thermal conductivity of the connection can improve, for example the cooling of the components involved in the connection. In particular, the use of copper for the nanowires and/or for the contact faces is preferred for this purpose.

The described connection furthermore can be of a particularly simple design and can be formed without tools. Merely the contact faces to be connected and the connection element have to be guided towards one another. Heating and application of pressure can be optional and are not absolutely necessary.

In the described method the contact faces of the components are connected to one another indirectly via the connection element. This has the advantage that nanowires do not have to be provided on any of the components. It is sufficient that the nanowires are provided on the connection element. This can facilitate the execution of the method and in particular can also extend the field of application of the method to those contact faces that are not accessible or only poorly accessible for growth of the nanowires. Furthermore, the nanowires can be grown locally, separately from the components. Equally, it is alternatively preferred that a plurality of nanowires is provided also on the contact face of the first component and/or on the contact face of the second component. In this case the connection between the nanowires on the relevant connection face and the corresponding contact face is formed.

In a further preferred embodiment of the method, step B) is performed at room temperature.

The described connection between the contact faces and the connection faces can be formed already at room temperature. Here, it is preferred that the connection element is pressed against the contact faces to form the connection. The pressure used here preferably lies in the range of 2 MPa and 200 MPa, in particular in the range of 5 MPa and 20 MPa. A pressure of 10 MPa is particularly preferred.

It is preferred that, even after completion of step B), no heating occurs. Damage to the components as a result of the action of temperature can thus be prevented.

In a further preferred embodiment, the method also comprises:
C) heating at least the contact faces of the components to a temperature of at least 90° C., in particular to at least 150° C.

The contact faces of the components are heated to a temperature of at least 90° C., preferably to a temperature of at least 150° C. The temperature preferably lies in the range of 90° C. to 300° C. Also in the present embodiment it is preferred that step B) is performed at room temperature. This means that the heating takes place only once the connection in accordance with step B) has been formed. The connection thus formed is strengthened by the heating. It is particularly preferred to preheat the components to be connected to between 130° C. and 170° C., in particular to 150° C., and then to connect them to one another with a temperature increase to between preferably 190° C. and 230° C., in particular to 210° C., for 0.5 to 2 seconds, in particular for 1 second.

As a result of the heating according to step d), the nanowires connect particularly well to the contact faces of the components. Accordingly, it is sufficient that only the contact faces are heated. In practice, with a heating of this kind, it is not routinely possible to distinguish whether the contact faces, the nanowires, the connection element and/or the two components are heated partially or entirely. This is particularly the case if thermally conductive materials are used. A (co-)heating of components other than the contact faces is not necessary for the forming of the connection, but also is not detrimental. The heating according to step C) can thus be performed in particular in that the two components and the connection element are heated collectively, for example in an oven. Alternatively, however, it is also possible to introduce heat locally into the region of the connection, in particular into the region of the contact faces.

For the forming of the connection, it can be sufficient that the described minimum temperature is achieved once at least temporarily. Maintaining the minimum temperature is not necessary. However, it is preferred that the temperature to which heating is performed in accordance with step C) is maintained for at least 2 seconds, preferably maintained for at least 10 seconds. It can thus be ensured that the connection is formed as desired. In principle, maintaining the temperature for longer is not detrimental.

In a further preferred embodiment of the method, the connection element, at least for a part of the heating, is pressed against the first contact face and/or against the second contact face, by a pressure of at least 5 MPa, in particular at least 15 MPa, and/or of at most 200 MPa, in particular of 70 MPa. This can be achieved in particular in that the connection element is pressured against the corresponding component.

The used pressure preferably lies in the range of 5 MPa and 200 MPa, in particular in the range of 15 MPa and 70 MPa. A pressure of 20 MPa is particularly preferred.

The pressure is preferably above the stated lower limit at least in a period of time in which the temperature exceeds the specified lower limit. In this regard, the nanowires and the contact face are thus exposed, at least in this period of time, both to an appropriate pressure and an appropriate temperature. The connection can thus be formed by the action of pressure and temperature.

The connection element is preferably adapted to the components that are to be connected to one another. In particular it is preferred that the connection faces are each formed in a manner complementary to the corresponding contact face of the components. An unevenness of the contact faces can thus be compensated for particularly well using the connection element.

In particular, a preferred embodiment of the method is one in which the first connection face is curved inwardly and the contact face of the first component is curved outwardly or the first connection face is curved outwardly and the contact face of the first component is curved inwardly, and/or the second connection face is curved inwardly and the contact face of the second component is curved outwardly or the second connection face is curved outwardly and the contact face of the second component is curved inwardly.

In this embodiment the connection faces are each curved in a manner complementary to the corresponding contact face of the components.

As a further aspect of the invention, an arrangement is presented which has:
a connection element with a first connection face (3) and a second connection face (3) opposite the first connection face, wherein a distance between the first connection face and the second connection face varies over the connection element,
a first component, which is connected to the first connection face of the connection element by means of a plurality of nanowires, and
a second component, which is connected to the second connection face of the connection element by means of a plurality of nanowires.
   The described advantages and features of the connection element, of the method for producing the connection element, and of the method for connecting the first component to the second component are applicable and transferrable to the arrangement, and vice versa. The arrangement can be obtained by the method for connecting the first component to the second component. The connection element of the arrangement is preferably formed similarly to the previously described connection element.

The connections of the connection element to the components are formed via nanowires. The nanowires between the first connection face and the contact face of the first component may have been provided only on the first connection face, only on the contact face of the first component, or both on the first connection face and on the contact face of the first component, before the forming of the corresponding connection. The same is true for the connection to the second component. Here, the variants for the first component and for the second component can be combined with one another arbitrarily, resulting in a total of nine variants.

The invention will be explained hereinafter with reference to the figures. The figures show particularly preferred exemplary embodiments, to which the invention is not limited, however. The figures and the size ratios shown therein are merely schematic. The drawings show:

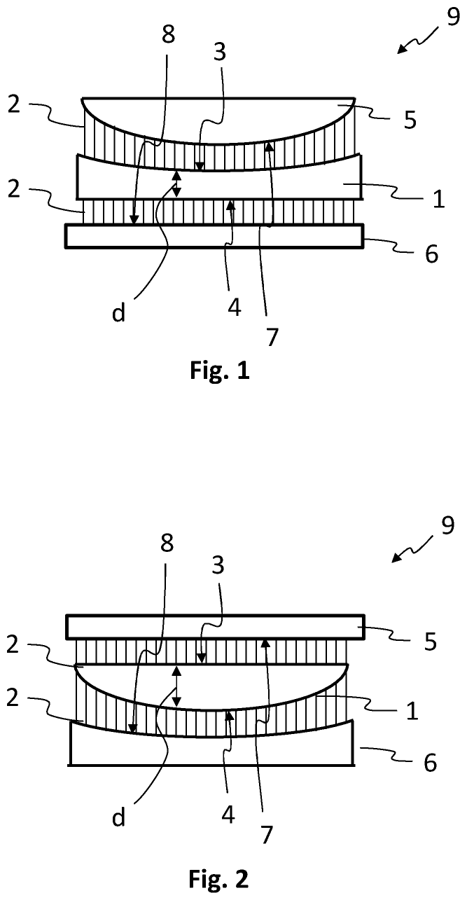

FIGS. 1 and 2: two embodiments of an arrangement according to the invention,

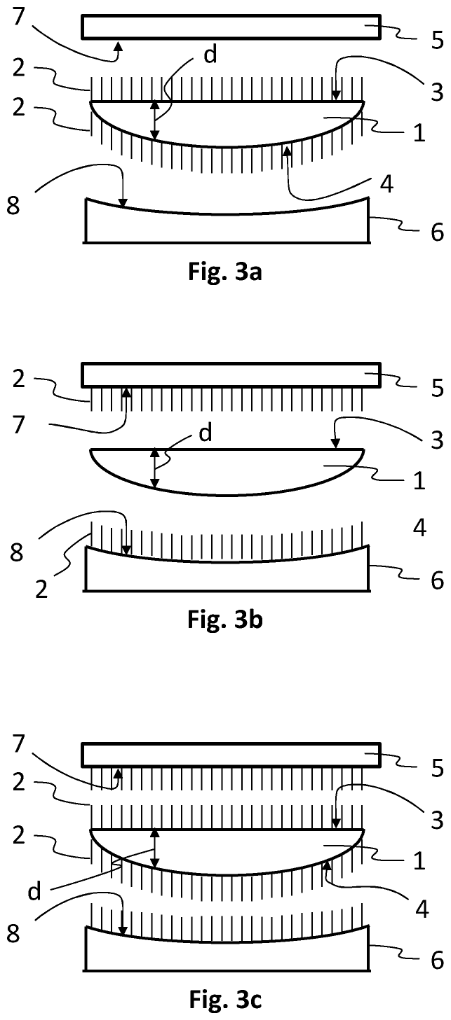

FIGS. 3a to 3c: three ways of obtaining the arrangement from FIG. 2,

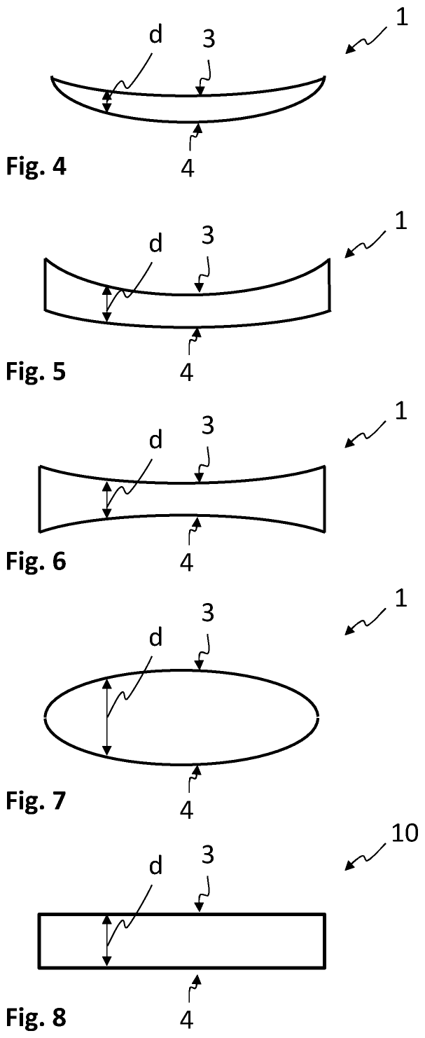

FIGS. 4 to 7: four embodiments of a connection element according to the invention without the nanowires,

FIG. 8: a starting element from which the connection elements from FIGS. 1 to 7 can be obtained,

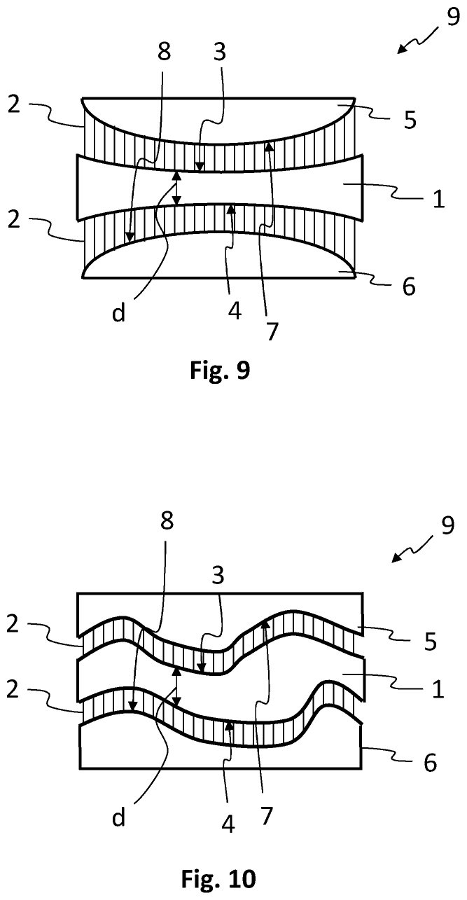

FIGS. 9 and 10: two further embodiments of an arrangement according to the invention.

FIG. 1 shows an arrangement 9 with a connection element 1, a first component 5 and a second component 6. The connection element 1 has a first connection face 3 and a second connection face 4 opposite the first connection face 3. A distance d between the first connection face 3 and the second connection face 4 varies over the connection element 1. This is the case in the shown embodiment since the first connection face 3 is curved outwardly and the second connection face 4 is flat.

The first component 5 is connected to the first connection face 3 of the connection element 1 via a plurality of nanowires 2. The second component 6 is connected to the second connection face 4 of the connection element 1 via a plurality of nanowires 2. The first component 5 has an inwardly curved contact face 7 and the second component 6 has a flat contact face 8.

FIG. 2 shows a further embodiment of an arrangement 9. Unless described otherwise, the description of FIG. 1 applies similarly. The arrangement 9 shown in FIG. 2 is a further example of the fact that one of the connection faces—here the first connection face 3—is curved outwardly and the other of the connection faces 4 is flat. The first component 5 has an outwardly curved contact face 7 and the second component 6 has a flat contact face 8.

The arrangements 9 from FIGS. 1 and 2 can each be obtained using the following method:
A) providing the connection element 1,
B) bringing together the contact face 7 of the first component 5 with the first connection face 3 of the connection element 1 and bringing together the contact face 8 of the second component 6 with the second connection face 4 of the connection element 1.
   FIGS. 3a to 3c show three ways of obtaining the arrangement 9 from FIG. 2. For example, prior to the bringing together in accordance with step B), the nanowires 2 can be present only on the two connection faces 3, 4 (FIG. 3a), only on the contact faces 7, 8 of the two components 5, 6 (FIG. 3b), or both on the two connection faces 3, 4 and on the contact faces 7, 8 of the two components 5, 6 (FIG. 3c).

FIGS. 3 to 6 show four (further) embodiments of connection elements 1. The connection elements 1 are shown without the nanowires 2 for reasons of clarity. The connection elements 1 from FIGS. 3 to 6 can be part of an arrangement 9, similarly to FIGS. 1 and 2.

FIGS. 4 and 5 show two embodiments of a connection element 1, in which one of the connection faces—here the second connection face 4—is curved outwardly and the other connection face 3 is curved inwardly with a different radius of curvature. In FIG. 4 the radius of curvature of the first connection face 3 is greater than the radius of curvature of the second connection face 4. In FIG. 5 the radius of curvature of the first connection face 3 is smaller than the radius of curvature of the second connection face 4.

FIG. 6 shows a connection element 1, in which both connection faces 3, 4 are curved inwardly.

FIG. 7 shows a connection element 1, in which both connection faces 3, 4 are curved outwardly.

FIG. 8 shows a starting element 10 (not shown true to scale) from which the connection elements 1 from FIGS. 1 to 7 can be produced. In the starting element 10, both connection faces 3, 4 are formed flat, so that in this regard the distance d between the two connection faces 3, 4 is constant over the starting element 10.

The connection elements 1 can each be obtained using the following method:
a) providing the starting element 10,
b) deforming the starting element 10, in particular by stamping, so that the distance d between the first connection face 3 and the second connection face 4 varies over the starting element 19,
c) providing a plurality of nanowires 2 on the first connection face 3 and on the second connection face 4 of the starting element 10, whereby the connection element 1 is obtained.
   FIGS. 9 and 10 show two further embodiments of an arrangement 9. The description of FIGS. 1 and 2 applies similarly, unless stated otherwise. In FIG. 9 the connection element from FIG. 6 is shown. A further connection element 1 is shown in FIG. 10. It should thus be clarified that the connection element 1 can have any form, provided the distance d between the connection faces 3, 4 is not constant over the connection element 1.

### LIST OF REFERENCE SIGNS

1 connection element
2 nanowire
3 first connection face
4 second connection face
5 first component
6 second component
7 contact face of the first component
8 contact face of the second component
9 arrangement
10 starting element
d distance between the connection faces

1. Connection element with a plurality of nanowires on a first connection face and/or on a second connection face opposite the first connection face, wherein a distance (d) between the first connection face and the second connection face varies over the connection element.

2. Connection element according to claim 1, wherein one of the connection faces is curved and the other of the connection faces is flat.

3. Connection element according to claim 1, wherein one of the connection faces is curved outwardly and the other of the connection faces is curved inwardly with a different radius of curvature.

4. Connection element according to claim 1, wherein the connection faces are both curved inwardly or both outwardly.

5. Method for producing a connection element, comprising:
a) providing a starting element having a first connection face and/or a second connection face opposite the first connection face, wherein a distance (d) between the first connection face and the second connection face is constant over the starting element,
b) deforming the starting element so that the distance (d) between the first connection face and the second connection face varies over the starting element,
c) providing a plurality of nanowires on the first connection face and on the second connection face of the starting element, whereby the connection element is obtained.

6. Method according to claim 5, wherein the starting element is deformed in step b) by stamping.

7. Method for connecting a first component to a second component, comprising:
A) providing a connection element having a plurality of nanowires on a first connection face and/or on a second connection face opposite the first connection face, wherein a distance (d) between the first connection face and the second connection face varies over the connection element,
B) bringing together a contact face of the first component with the first connection face of the connection element and bringing together a contact face of the second component with the second connection face of the connection element.

8. Method according to claim 7,
wherein the first connection face is curved inwardly and the contact face of the first component is curved outwardly, or the first connection face is curved outwardly and the contact face of the first component is curved inwardly,
and/or
wherein the second connection face is curved inwardly and the contact face of the second component is curved outwardly, or the second connection face is curved outwardly and the contact face of the second component is curved inwardly.

9. Arrangement, having
a connection element with a first connection face and a second connection face opposite the first connection face, wherein a distance (d) between the first connection face and the second connection face varies over the connection element,
a first component, which is connected to the first connection face of the connection element by means of a plurality of nanowires, and
a second component, which is connected to the second connection face of the connection element by means of a plurality of nanowires.
